(19) United States
(12) Patent Application Publication
(10) Pub. No.: US 2012/0017973 A1
(43) Pub. Date: Jan. 26, 2012

(54) IN-LINE DEPOSITION SYSTEM

(76) Inventors: Markus E. Beck, Scotts Valley, CA (US); Ashish Bodke, San Jose, CA (US); Yu-Jen Chang, San Jose, CA (US); Yacov Elgar, Sunnyvale, CA (US); Raffi Garabedian, Los Altos, CA (US); Erel Milshtein, Cupertino, CA (US)

(21) Appl. No.: 13/189,273

(22) Filed: Jul. 22, 2011

Related U.S. Application Data
(60) Provisional application No. 61/367,111, filed on Jul. 23, 2010.

(51) Int. Cl. C23C 16/44; H01L 31/02; B05C 11/00

(52) U.S. Cl. 136/252; 118/719; 118/708; 118/712; 427/248.1

(57) ABSTRACT

A deposition system includes a load lock chamber for receiving a substrate and exposing a substrate to a load lock temperature and load lock pressure suitable to prepare a substrate for subsequent low-pressure and high-temperature processing or for ambient temperature and pressure conditions.

### CLAIM FOR PRIORITY

This application claims priority under 35 U.S.C. §119(e) to Provisional U.S. Patent Application Ser. No. 61/367,111, filed on Jul. 23, 2010, which is hereby incorporated by reference in its entirety.

### TECHNICAL FIELD

This invention relates to a high throughput in-line tool. The high throughput in-line tool can be used in an atomic layer deposition.

### BACKGROUND

Atomic layer deposition (ALD) is a thin film deposition technique that is based on the sequential use of a gas phase chemical process. A major limitation of ALD is its low deposition rate.

### DESCRIPTION OF DRAWINGS

FIG. 1 illustrates a high throughput in-line tool for atomic layer deposition.

FIG. 2 illustrates a high throughput in-line tool for atomic layer deposition.

FIG. 3 illustrates a cross section of a process chamber and reaction chamber.

FIG. 4 illustrates a top view of a process chamber and reaction chamber.

FIG. 5 illustrates a high throughput in-line tool for atomic layer deposition.

FIG. 6 illustrates a high throughput in-line tool for atomic layer deposition.

FIG. 7 illustrates a cross section of a process chamber and reaction chamber.

FIG. 8 illustrates a control diagram of a high throughput in-line tool for atomic layer deposition.

### DETAILED DESCRIPTION

Photovoltaic devices can include multiple layers formed on a substrate (or superstrate). For example, a photovoltaic device can include a conducting layer, a semiconductor absorber layer, a buffer layer, a semiconductor window layer, and a transparent conductive oxide (TCO) layer, formed in a stack on a substrate. Each layer may in turn include more than one layer or film. For example, the semiconductor window layer and semiconductor absorber layer together can be considered a semiconductor layer. The semiconductor layer can include a first film created (for example, formed or deposited) on the TCO layer and a second film created on the first film. Additionally, each layer can cover all or a portion of the device and/or all or a portion of the layer or substrate underlying the layer. For example, a “layer” can mean any amount of any material that contacts all or a portion of a surface.

Atomic layer deposition is a thin film deposition technique that is based on the sequential use of a gas phase chemical process. By using ALD, film thickness depends only on the number of reaction cycles, which makes the thickness control accurate and simple. Unlike chemical vapor deposition (CVD), there is less need of reactant flux homogeneity, which gives large area (large batch and easy scale-up) capability, excellent conformality and reproducibility, and simplifies the use of solid precursors. Furthermore, the growth of different multilayer structures is straight forward. However, a major limitation of ALD is its low deposition rate. Therefore, multiple substrates are processed at the same time in most of practical application.

The growth of material layers by ALD consists of repeating the following characteristic four steps: 1) exposure of the first precursor, 2) purge or evacuation of the reaction chamber to remove the non-reacted precursors and the gaseous reaction by-products, 3) exposure of the second precursor—or another treatment to activate the surface again for the reaction of the first precursor, 4) Purge or evacuation of the reaction chamber. Each reaction cycle adds a given amount of material to the surface, referred to as the growth per cycle. The majority of ALD reactions use two chemicals, typically called precursors. These precursors react with a surface one-at-a-time in a sequential manner. By exposing the precursors to the growth surface repeatedly, a thin film is deposited. In some embodiments, manufacturing process can include more than one ALD, which can be performed in different reaction chambers.

Similar in chemistry to chemical vapor deposition (CVD), except that the ALD reaction breaks the CVD reaction into two half-reactions, keeping the precursor materials separate during the reaction. Additionally, ALD film growth is self-limited and based on surface reactions, which makes achieving atomic scale deposition control possible. By keeping the precursors separate throughout the coating process, atomic layer thickness control of film grown can be obtained as fine as atomic/molecular scale per monolayer. ALD includes releasing sequential precursor gas pulses to deposit a film one layer at a time on the substrate. The precursor gas can be introduced into a process chamber and produces a precursor monolayer of material on the device surface. A second precursor of gas can be then introduced into the chamber reacting with the first precursor to produce a monolayer of film on the substrate/absorber surface.

The precursor monolayers (for example, a metal precursor monolayer or chalcogen precursor monolayer) can have a thickness of less than about two molecules, for example, about one molecule. After the precursors react, the resulting metal chalcogenide layer can also have a thickness of less than about two molecules, for example, about one molecule. A monolayer, for example, a precursor monolayer or a metal chalcogenide monolayer can be continuous or discontinuous and can contact all or a portion of a surface. For example, a monolayer can contact more that about 80%, more than about 85%, more than about 90%, more than about 95%, more than about 98%, more than about 99%, more than about 99.9%, or about 100% of a surface. ALD has two fundamental mechanisms: chemisorption saturation process and sequential surface chemical reaction process. Given the nature of ALD, a specifically designed feed is desired for large scale manufacturing. A high throughput in-line tool is developed for atomic layer deposition.

The high throughput in-line tool has the capability to be integrated into a production line coating individual substrates and to handle multiple substrates, wafers or panels automatically and simultaneously. In some embodiments, the tool can include multiple process and/or reaction chambers capable of applying ALD coatings simultaneously onto substrates, wafers or panels. In some embodiments, multiple chambers can be used to deposit layers sequentially. Therefore, if the growth temperature or pressure varies in a deposition process, the substrate can stay in the same tool, but be moved to a different chamber for a sequential stage. The high throughput in-line tool can be used in any suitable deposition process, such as chemical vapor deposition (CVD), plasma-enhanced chemical vapor deposition (PECVD), metal-organic chemical vapor deposition (MOCVD), atmospheric pressure chemical vapor deposition (APCVD), or low pressure chemical vapor deposition (LPCVD), or any other suitable technique.

In one aspect, a deposition system can include an inlet load lock chamber for receiving a substrate and exposing a substrate to a load lock temperature and load lock pressure suitable to prepare a substrate for subsequent low-pressure and high-temperature processing. The system can include a process chamber including an interior for receiving a substrate from the inlet load lock chamber and exposing a substrate to a process temperature and process pressure suitable to prepare a substrate for a deposition process. The system can include a reaction chamber positioned in the interior of the process chamber having a deposition temperature and deposition pressure and configured to form a layer of material on a substrate by atomic vapor deposition. The system can include an outlet load lock chamber for receiving a substrate from the reaction chamber and exposing a substrate to a temperature and pressure suitable to remove a substrate from the process chamber into ambient conditions.

The deposition process can include atomic layer deposition. The system can include at least one additional reaction chamber positioned in the interior of the process chamber. The system can include a second process chamber including a second reaction chamber. The second process chamber can be positioned adjacent to the process chamber to allow a substrate to be transferred from the first process chamber to the second process chamber for a sequential deposition process.

The system can include a substrate lift beneath a substrate position in the reaction chamber to lift a substrate into the reaction chamber and seal the reaction chamber. The system can include a conveyor for transferring a substrate to the inlet load lock chamber. The system can include a conveyor for transferring a substrate from the outlet load lock chamber to the product line. The system can include a transfer chamber between the first process chamber and the second process chamber for transferring a substrate to each process chamber for sequential processing.

The system can include a robot for transferring a substrate from the transfer chamber. The system can include a conveyor for transferring a substrate from the transfer chamber. The system can include a substrate cassette including a plurality of substrates capable of being transferred between the transfer chamber and one of the process chambers. The plurality of substrates can be parallel processed in the process chamber.

The system can include a proportional integral derivative controller monitoring and controlling temperature and pressure conditions in the process chamber. The system can include a proportional integral derivative controller monitoring and controlling temperature and pressure conditions in Lne reaction chamber.

The system can include a main controller, a user interface, and a frame controller. The frame controller can control the deposition processing in the reaction chamber and the main controller can control transferring substrates to or from the production line. The system can include at least one temperature sensor for measuring the substrate temperature.

In another aspect, a deposition system can include an inlet/outlet load lock chamber for receiving a substrate and exposing a substrate to a load lock temperature and load lock pressure suitable to prepare a substrate to subsequent low-pressure and high-temperature processing and for exposing a substrate to a load lock temperature and load lock pressure suitable to remove a substrate from the process chamber into ambient conditions after deposition. The system can include at least two process chambers for receiving a substrate and exposing a substrate to a process temperature and process pressure suitable for subsequent deposition processing. The system can include at least two reaction chambers, each of which can be positioned in the interior of a process chamber, and each having a deposition temperature and deposition pressure and configured to form a layer of material on a substrate a deposition process. The system can include a transfer chamber for transferring substrates from the inlet/outlet load lock chamber to the process chambers before deposition and from the process chambers to the inlet/outlet load lock chamber after deposition.

The deposition process can include atomic layer deposition. Each reaction chamber can be a part of a process chamber and the process chambers can be provided in a cluster configuration surrounding the transfer chamber, in which a substrate can be transferred from a process chamber to another process chamber for a sequential deposition process. The system can include a substrate lift beneath a substrate position in one of the reaction chamber to lift a substrate into the reaction chamber and seal the reaction chamber. The system can include a transfer robot configured to transfer substrates from one process chamber to another process chamber. The system can include conveyor transferring the substrate from the load lock chamber a downstream.

In another aspect, a method of forming a material layer on a substrate can include maintaining an inlet load lock chamber at a load lock temperature and load lock pressure suitable to prepare a substrate for subsequent low-pressure and high-temperature processing. The method can include transferring the substrate to the inlet load lock chamber. The method can include maintaining a process chamber at a process temperature and process pressure suitable to prepare the substrate for a subsequent deposition process. The method can include transferring the substrate to the process chamber. The method can include maintaining a reaction chamber at a deposition temperature and deposition pressure suitable to deposit a material layer on the substrate, wherein the reaction chamber is positioned inside the process chamber. The method can include depositing a material layer on the substrate. The method can include removing the substrate from the reaction chamber.

The substrate can be removed from the reaction chamber into a transfer station positioned in the process chamber. The method can include maintaining a second reaction chamber at a deposition temperature and deposition pressure suitable to deposit a material layer on the substrate, wherein the second reaction chamber is positioned inside the process chamber and transferring the substrate from the transfer station to the second reaction station.

The method can include monitoring and controlling temperature and pressure conditions in the process chamber by a proportional integral derivative controller. The method can include monitoring and controlling temperature and pressure conditions in the reaction chamber by a proportional integral derivative controller. The method can include controlling the deposition processing in the reaction chamber by a frame controller and controlling substrates transferring from/to the production line by a main controller.

The method can include lifting the substrate to the reaction chamber and sealing the reaction chamber during deposition, wherein the reaction chamber is a part of the process chamber. The method can include measuring the substrate temperature by at least one pyrometer. The method can include measuring the substrate temperature by at least one contact sensor, such as a thermocouple or platinum resistance thermometer.

In another aspect, a photovoltaic device can include a substrate and an atomic layer deposited film formed on the substrate. The atomic layer deposited film can be formed by positioning the substrate in an inlet load lock chamber maintained at a load lock temperature and load lock pressure suitable to prepare the substrate for subsequent low-pressure and high-temperature processing, transferring the substrate to a process chamber maintained at a process temperature and process pressure suitable to prepare the substrate for a subsequent deposition process, transferring the substrate into a reaction chamber positioned inside the process chamber, and atomic-layer depositing a material layer on the substrate.

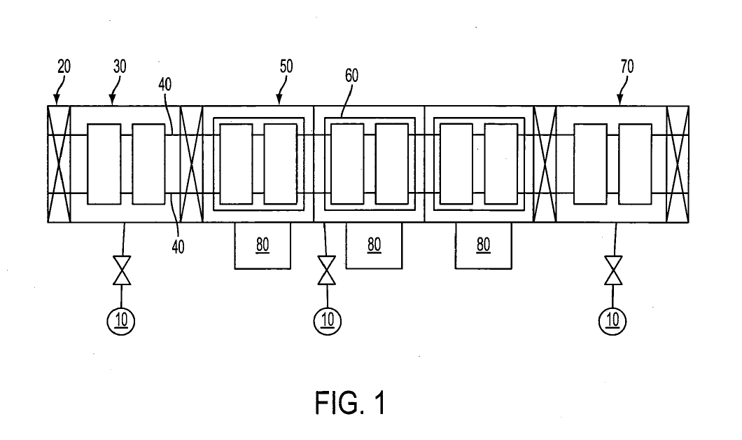

As shown in FIG. 1, a high throughput in-line tool can include a serial configuration, which includes isolation valve 20, inlet load lock chamber 30, process chamber 50, and reaction chamber 60, wherein an atomic layer deposition is performed. The high throughput in-line tool can include more than one process chamber 50 and reaction chamber 60. Pump 10 can be included to provide the necessary pressure for transferring and processing the substrates.

Each reaction chamber can be a part of a process chamber and the process chambers are provided in a serial configuration, in which a substrate is transferred from a process chamber to another process chamber for sequential deposition process. Roller motion track 40 can be included to transfer substrates between different chambers and move them along the production line. Each reaction chamber 60 can include gas box 80 for providing the precursor gas. Each gas flow from gas box 80 can be delivered as a pulse, in which the precursor gas is directed toward the substrate and then ceases being directed toward the substrate. The particular lengths and rates of the respective flowing, and the times there-between, can also be optimized to achieve the desired film thickness and composition. The cycle can be repeated with the same or different precursors to form the same or different metal chalcogenide monolayers. One or more of the same metal chalcogenide monolayers can form one metal chalcogenide layer.

ALD can be used to deposit any suitable material layer. For example, ALD can be used to deposit a layer in a photovoltaic device. Specifically, ALD can be used to deposit a buffer layer of a copper-indium-gallium-diselenide (CIGS) photovoltaic device including a metal chalcogenide, such as indium sulfide (e.g., In₂S₃), indium oxide (e.g., In₂O₃), or indium selenide (e.g., In₂Se₃) (or combinations thereof), zinc sulfide (e.g., ZnS), zinc oxide (e.g., ZnO), or zinc selenide (ZnS) (or combinations thereof).

These layers can be formed from one or more formed monolayer. For example, a first buffer monolayer can include indium sulfide (e.g., In₂S₃), indium oxide (e.g., In₂O₃), or indium selenide (e.g., In₂Se₃) or any suitable indium chalcogenide (e.g., In₂(O, S, Se)₃), or zinc sulfide (e.g., ZnS), zinc oxide (e.g., ZnO), or zinc selenide (e.g., ZnSe) or any suitable zinc chalcogenide (e.g., Zn(O, S, Se)). One or more additional monolayers of the same or differing compositions can be formed on the first monolayer. For example, the second monolayer can include indium sulfide (e.g., In₂S₃), indium oxide (e.g., In₂O₃), or indium selenide (e.g., In₂Se₃) or any suitable indium chalcogenide (e.g., In₂(O, S, Se)₃), or zinc sulfide (e.g., ZnS), zinc oxide (e.g., ZnO), or zinc selenide (e.g., ZnSe) or any suitable zinc chalcogenide (e.g., Zn(O, S, Se)).

Each chamber can be maintained at any suitable conditions, including any suitable temperature and pressure. Inlet load lock chamber 30 can be maintained at a temperature suitable to prepare a substrate contained therein for subsequent low-pressure and high-temperature processing. “Low-pressure” processing can include processing that occurs at 0-500 Torr, or 0-100 Torr, or 1-50 Torr. “High-temperature” processing can include processing that occurs between 75 degrees C. and 300 degrees C., or higher. Inlet load lock chamber 30 can have a load lock temperature of about 15 degrees C. to about 500 degrees C., about 15 degrees C. to about 400 degrees C., about 15 degrees C. to about 300 degrees C., about 15 degrees C. to about 200 degrees C., about 15 degrees C. to about 100 degrees C., about 400 degrees C. to about 500 degrees C., about 300 degrees C. to about 400 degrees C., about 200 degrees C. to about 300 degrees C., about 100 degrees C. to about 200 degrees C., about 15 degrees C. to about 50 degrees C., about 25 degrees C. to about 75 degrees C., or about 25 degrees C. to about 50 degrees C. Inlet load lock chamber 30 can have any suitable load lock pressure, including 10⁻⁷-1000 Torr, 10⁻⁷-500 Torr, or 10⁻⁷-100 Torr

Process chamber 50 can have a process temperature greater than the load lock chamber of load lock chamber 30. Process chamber 50 can have a process temperature of about 50 degrees C. to about 500 degrees C., about 50 degrees C. to about 400 degrees C., about 50 degrees C. to about 300 degrees C., about 50 degrees C. to about 200 degrees C., about 50 degrees C. to about 100 degrees C., about 400 degrees C. to about 500 degrees C., about 300 degrees C. to about 400 degrees C., about 200 degrees C. to about 300 degrees C., about 100 degrees C. to about 200 degrees C., about 50 degrees C. to about 200 degrees C., about 50 degrees C. to about 175 degrees C., about 50 degrees C. to about 150 degrees C., about 50 degrees C. to about 100 degrees C., about 75 degrees C. to about 200 degrees C., about 75 degrees C. to about 175 degrees C., about 75 degrees C. to about 150 degrees C., or about 75 degrees C. to about 500 degrees C. Process chamber 50 can have any suitable process pressure, including 10⁻⁷-1000 Torr, 10⁻⁷-500 Torr, or 10⁻⁷-100 Torr.

Reaction chamber 60 can have a deposition temperature, which can be greater than the process temperature of process chamber 50. Reaction chamber 60 can have a deposition temperature of about 75 degrees C. to about 500 degrees C., about 75 degrees C. to about 400 degrees C., about 75 degrees C. to about 200 degrees C., about 75 degrees C. to about 100 degrees C., about 400 degrees C. to about 500 degrees C., about 300 degrees C. to about 400 degrees C., about 200 degrees C. to about 300 degrees C., about 75 degrees C. to about 300 degrees C., about 75 degrees C. to about 270 degrees C., about 75 degrees C. to about 250 degrees C., about 75 degrees C. to about 150 degrees C., about 100 degrees C. to about 300 degrees C., about 100 degrees C. to about 200 degrees C., about 100 degrees C. to about 150 degrees C., about 150 degrees C. to about 350 degrees C., about 150 degrees C. to about 300 degrees C., about 150 degrees C. to about 250 degrees C., about 150 degrees C. to about 200 degrees C., or about 170 degrees C. to about 500 degrees C. Reaction chamber 60 can be have any suitable deposition pressure, including 10⁻⁷-1000 Torr, 10⁻⁷-20 Torr, 10⁻⁷-10 Torr, 5-10 Torr, 5 mTorr-500 mTorr, 5 mTorr-100 mTorr, or 5 mTorr-50 mTorr.

After the depositions are completed, substrates can be transferred to outlet load lock chamber 70. Outlet load lock chamber 70 can provide a necessary transfer condition compatible with the ambient condition of a production line. Outlet load lock chamber 70 can have an outlet load lock temperature less than the deposition temperature of reaction chamber 60. Outlet load lock chamber 70 can have a temperature about equal to the load lock temperature of inlet load lock 30. Outlet load lock chamber 70 can have a temperature of about 15 degrees C. to about 500 degrees C., about 15 degrees C. to about 400 degrees C., about 15 degrees C. to about 300 degrees C., about 15 degrees C. to about 200 degrees C., about 15 degrees C. to about 100 degrees C., about 400 degrees C. to about 500 degrees C., about 300 degrees C. to about 400 degrees C., about 200 degrees C. to about 300 degrees C., about 100 degrees C. to about 200 degrees C., about 15 degrees C. to about 75 degrees C., about 15 degrees C. to about 50 degrees C., about 25 degrees C. to about 75 degrees C., or about 25 degrees C. to about 500 degrees C. Outlet load lock chamber 70 can have any suitable load lock pressure, including 10⁻⁷-1000 Torr, 10⁻⁷-500 Torr, or 10⁻⁷-100 Torr. The substrate can be transferred to/from the outlet/inlet load lock chamber by a robot or conveyor. Any suitable material can be deposited in reaction chamber 60, including compounds including zinc, oxygen, and/or sulfur, such as zinc oxide, zinc sulfide, and combinations thereof, or compounds including indium and sulfur, such as indium sulfide.

Process chamber 50 can have any suitable temperature and pressure, including a temperature and pressure suitable to prepare a substrate from inlet load lock chamber 30 for a subsequent deposition process, such as atomic layer deposition.

In some embodiments, the high throughput in-line tool can include a transfer chamber, wherein more than one substrate can be transferred from the transfer chamber to the process chambers for sequential processing. The substrate can be transferred to/from the transfer chamber by a robot or conveyor. The substrates can be transferred in a substrate cassette including a plurality of substrates.

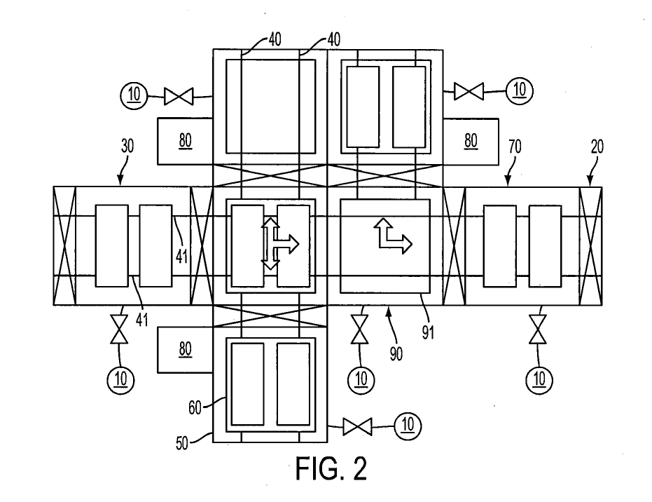

The high throughput in-line tool can include a proportional integral derivative controller monitoring and controlling temperature and pressure conditions in the process chambers and reaction chambers. As shown in FIG. 2, the high throughput in-line tool can include transfer chamber 90 and transfer table 91. The high throughput in-line tool can include at least one pyrometer or contact sensor (such as a thermocouple or platinum resistance thermometer) measuring the substrate temperature.

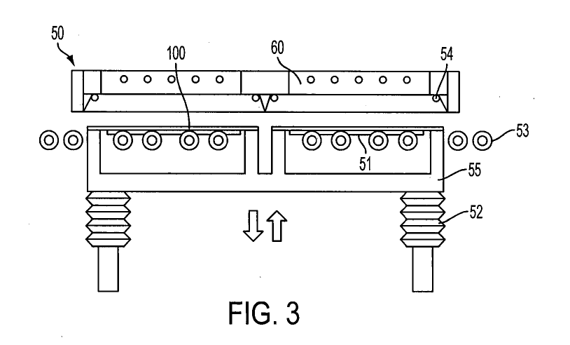

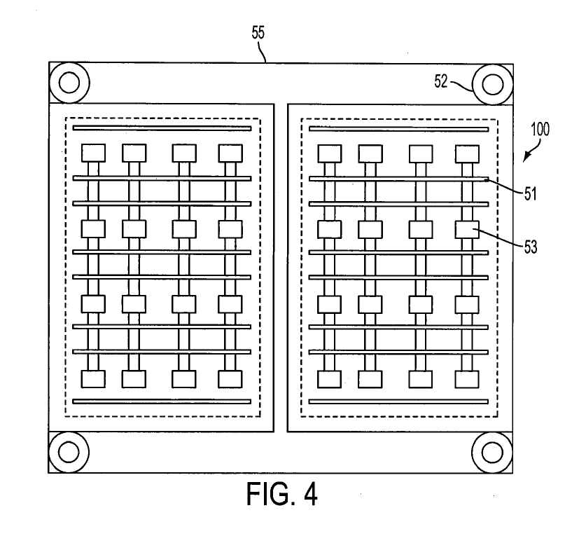

The high throughput in-line tool can include a substrate lift and seal module to lift the substrate to the reaction chamber. As shown in FIGS. 3 and 4, in process chamber 50, the high throughput in-line tool can include substrate conveyor or roller 53 to transfer substrates 100 to pedestal 55. Heater 51 can be included to provide the necessary temperature for processing substrates 100. After substrates 100 are positioned below reaction chambers 60. Lifter 52 can be used to lift pedestal 55 including substrates 100 to reaction chambers 60. Seal 54 can be included to provide necessary processing conditions for ALD.

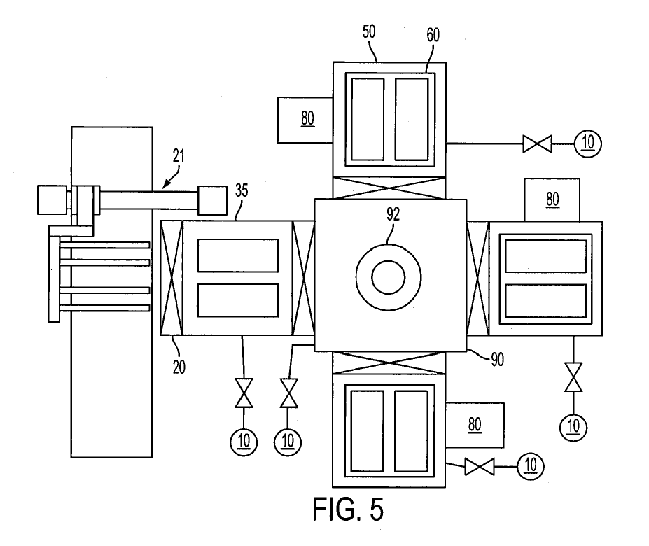

In some embodiments, a high throughput in-line tool for atomic layer deposition can include an inlet/outlet load lock chamber providing appropriate conditions, including to allow sequential processing of at least two substrates before deposition and transfer conditions compatible with the ambient condition of a production line after deposition, at least two process chambers providing appropriate conditions to allow sequential atomic layer deposition of at least two substrates, at least two reaction chambers, and a transfer chamber. The substrates can be transferred by a transfer module from the inlet/outlet load lock chamber to the process chambers before deposition and from the process chambers to the inlet/outlet load lock chamber after deposition. As shown in FIG. 5, the high throughput in-line tool can include an asymmetrical cluster configuration. Inlet/outlet load lock chamber 35 can be included for both substrate input/output. The transfer module can include robot 92 in transfer chamber 90 to transfer substrates to/from different process chambers. Robot 92 can be configured to transfer the substrates to each process chamber in a predetermined order. External loader 21 can be included to transfer substrates to/from the production line.

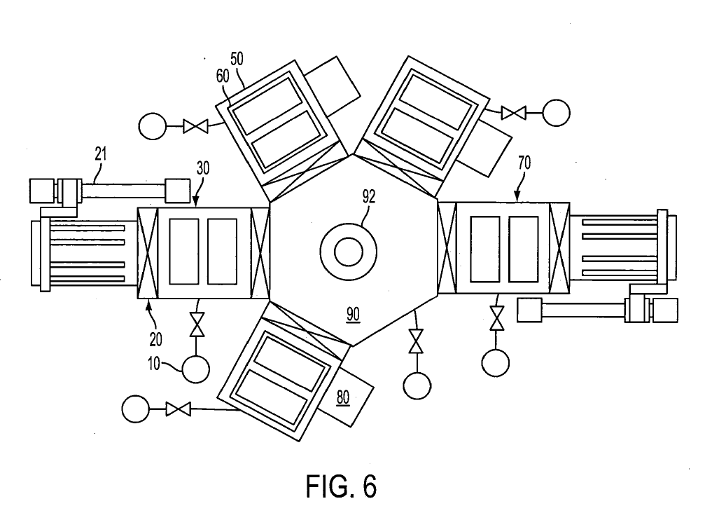

As shown in FIG. 6, in other embodiments, the high throughput in-line tool can include a symmetrical cluster configuration. Outlet load lock chamber 70 and inlet load lock chamber 30 can be positioned on opposite sides of the chamber cluster. Likewise, External loader 21 can positioned on opposite sides of the chamber cluster to transfer substrates to/from the production line.

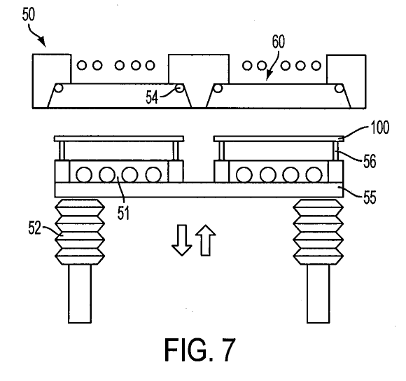

For the high throughput in-line tool with a cluster configuration, it can include a substrate lift and seal module to lift the substrate to the reaction chamber, as shown in FIG. 7. Robot 92 can transfer substrates 100 to pedestal 55 in process chamber 50. Heater 51 can be included to provide the necessary temperature for processing substrates 100. Spring/actuator 56 can be included to precisely positioning substrates 100. After substrates 100 are positioned below reaction chambers 60. Lifter 52 can be used to lift pedestal 55 including substrates 100 to reaction chambers 60. Seal 54 can be included to seal the reaction chamber providing necessary processing conditions for ALD.

In some embodiments, the high throughput in-line tool can include a main controller, a user interface, and a frame controller, wherein the frame controller can control the deposition processing in the reaction chambers, and the main controller controls substrates transferring from/to the production line.

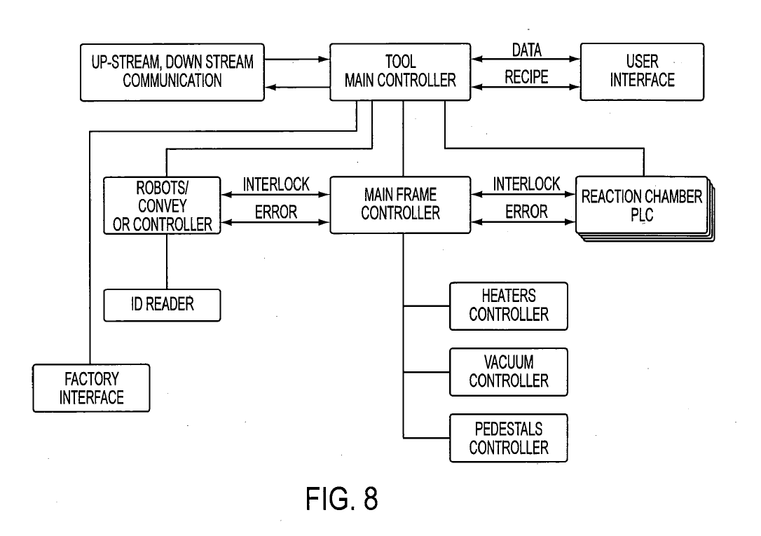

As shown in FIG. 8, a high throughput in-line tool for atomic layer deposition can have a control scheme including a tool main controller and a main frame controller. The main frame controller can communicate with a user interface on processing data and recipe. The tool main controller can also handle the up-stream and down-stream communication to cooperate the tool with the rest of production line. The main frame controller can interact with the programmable logic controller (PLC) or proportional integral derivative (PID) controller monitoring and controlling temperature and pressure conditions in the process chambers and reaction chambers. The main frame controller can also control or interact with the robots/conveyor controller. The tool can include heater controller, vacuum controller, and pedestal controller. The tool can include ID reader to identify different substrate during the ALD process.

While the invention has been shown and explained in the embodiment described herein, it is to be understood that the invention should not be confined to the exact showing of the drawings, and that any variations, substitutions, and modifications are intended to be comprehended within the spirit of the invention. Other embodiments are within the claims.

What is claimed is:

1. A deposition system comprising:
an inlet load lock chamber for receiving a substrate and exposing a substrate to a load lock temperature and load lock pressure suitable to prepare a substrate for subsequent low-pressure and high-temperature processing;
a process chamber comprising an interior for receiving a substrate from the inlet load lock chamber and exposing a substrate to a process temperature and process pressure suitable to prepare a substrate for a deposition process;
a reaction chamber positioned in the interior of the process chamber having a deposition temperature and deposition pressure and configured to form a layer of material on a substrate by the deposition process; and
an outlet load lock chamber for receiving a substrate from the reaction chamber and exposing a substrate to a temperature and pressure suitable to remove a substrate from the process chamber into ambient conditions.

2. The system of claim 1, wherein the deposition process comprises atomic layer deposition.

3. The system of claim 1, further comprising at least one additional reaction chamber positioned in the interior of the process chamber.

4. The system of claim 1, further comprising a second process chamber comprising a second reaction chamber, wherein the second process chamber is positioned adjacent to the process chamber to allow a substrate to be transferred from the first process chamber to the second process chamber for a sequential deposition process.

5. The system of claim 1, further comprising a substrate lift beneath a substrate position in the reaction chamber to lift a substrate into the reaction chamber and seal the reaction chamber.

6. The system of claim 1, further comprising a conveyor for transferring a substrate to the inlet load lock chamber.

7. The system of claim 1, further comprising a conveyor for transferring a substrate from the outlet load lock chamber to the product line.

8. The system of claim 4, further comprising a transfer chamber between the first process chamber and the second process chamber for transferring a substrate to each process chamber for sequential processing.

9. The system of claim 8, further comprising a robot for transferring a substrate from the transfer chamber.

10. The system of claim 8, further comprising a conveyor for transferring a substrate from the transfer chamber.

11. The system of claim 8, further comprising a substrate cassette comprising a plurality of substrates capable of being transferred between the transfer chamber and one of the process chambers, wherein the plurality of substrates can be parallel processed in the process chamber.

12. The system of claim 1, further comprising a proportional integral derivative controller monitoring and controlling temperature and pressure conditions in the process chamber.

13. The system of claim 1, further comprising a proportional integral derivative controller monitoring and controlling temperature and pressure conditions in the reaction chamber.

14. The system of claim 1, further comprising:
a main controller;
a user interface; and
a frame controller, wherein the frame controller controls the deposition processing in the reaction chamber and the main controller controls substrates transferring from/to the production line.

15. The system of claim 1, further comprising at least one temperature sensor for measuring the substrate temperature.

16. A deposition system comprising:
an inlet/outlet load lock chamber for receiving a substrate and exposing a substrate to a load lock temperature and load lock pressure suitable to prepare a substrate to subsequent low-pressure and high-temperature processing and for exposing a substrate to a load lock temperature and load lock pressure suitable to remove a substrate from the process chamber into ambient conditions after deposition;
at least two process chambers for receiving a substrate and exposing a substrate to a process temperature and process pressure suitable for subsequent deposition processing;
at least two reaction chambers, each of which is positioned in the interior of a process chamber, and each having a deposition temperature and deposition pressure and configured to form a layer of material on a substrate a deposition process; and
a transfer chamber for transferring substrates from the inlet/outlet load lock chamber to the process chambers before deposition and from the process chambers to the inlet/outlet load lock chamber after deposition.

17. The system of claim 16, wherein the deposition process comprises atomic layer deposition.

18. The system of claim 16, wherein each reaction chamber is a part of a process chamber and the process chambers are provided in a cluster configuration surrounding the transfer chamber, in which a substrate is transferred from a process chamber to another process chamber for a sequential deposition process.

19. The system of claim 16, further comprising a substrate lift beneath a substrate position in one of the reaction chamber to lift a substrate into the reaction chamber and seal the reaction chamber.

20. The system of claim 16, further comprising a transfer robot configured to transfer substrates from one process chamber to another process chamber.

21. The system of claims 16, comprising a conveyor transferring the substrate from the load lock chamber a down-stream.

22. A method of forming a material layer on a substrate comprising: maintaining an inlet load lock chamber at a load lock temperature and load lock pressure suitable to prepare a substrate for subsequent low-pressure and high-temperature processing;
transferring the substrate to the inlet load lock chamber;
maintaining a process chamber at a process temperature and process pressure suitable to prepare the substrate for a subsequent deposition process;
transferring the substrate to the process chamber;
maintaining a reaction chamber at a deposition temperature and deposition pressure suitable to deposit a material layer on the substrate, wherein the reaction chamber is positioned inside the process chamber;
depositing a material layer on the substrate; and
removing the substrate from the reaction chamber.

23. The method of claim 22, wherein the substrate is removed from the reaction chamber into a transfer station positioned in the process chamber.

24. The method of claim 23, further comprising maintaining a second reaction chamber at a deposition temperature and deposition pressure suitable to deposit a material layer on the substrate, wherein the second reaction chamber is positioned inside the process chamber and transferring the substrate from the transfer station to the second reaction station.

25. The method of claim 22, further comprising monitoring and controlling temperature and pressure conditions in the process chamber by a proportional integral derivative controller.

26. The method of claims 22, further comprising monitoring and controlling temperature and pressure conditions in the reaction chamber by a proportional integral derivative controller.

27. The method of claims 22, further comprising controlling the deposition processing in the reaction chamber by a frame controller and controlling substrates transferring from/to the production line by a main controller.

28. The method of claim 22, further comprising
lifting the substrate to the reaction chamber; and
sealing the reaction chamber during deposition, wherein the reaction chamber is a part of the process chamber.

29. The method of claim 22, further comprising measuring the substrate temperature by at least one pyrometer.

30. The method of claim 22, further comprising measuring the substrate temperature by at least one contact sensor.

31. A photovoltaic device comprising:
a substrate; and
an atomic layer deposited film formed on the substrate,
wherein the atomic layer deposited film is formed by positioning the substrate in an inlet load lock chamber maintained at a load lock temperature and load lock pressure suitable to prepare the substrate for subsequent low-pressure and high-temperature processing;
transferring the substrate to a process chamber maintained at a process temperature and process pressure suitable to prepare the substrate for a subsequent deposition process;
transferring the substrate into a reaction chamber positioned inside the process chamber; and
atomic-layer depositing a material layer on the substrate.
